(19) United States
(12) Patent Application Publication
(10) Pub. No.: US 2019/0250203 A1
(43) Pub. Date: Aug. 15, 2019

(54) Locating Short-Circuit Faults Through Utilizing Operating Times of Coordinated Numerical Directional Overcurrent Relays

(71) Applicants: Ali Ridha Ali, Halifax (CA); Mohamed El-Aref El-Hawary, Halifax (CA)

(72) Inventors: Ali Ridha Ali, Halifax (CA); Mohamed El-Aref El-Hawary, Halifax (CA)

(73) Assignee: Ali Ridha Ali, Halifax (CA)

(21) Appl. No.: 15/895,015

(22) Filed: Feb. 13, 2018

(51) Int. Cl. G01R 31/08; H02H 7/26

(52) U.S. Cl. CPC G01R 31/088; H02H 7/26

(57) ABSTRACT

Nowadays, there are different techniques used to effectively locate faults in electric power systems. These techniques are based on travelling wave, time-domain, phasor-domain, power quality data, superimposed components, and artificial intelligence (AI). Also, each one of these techniques has a specific application; such as locating faults in distribution, sub-transmission, transmission, or generation part. The grid itself could be a conventional or smart, large or micro-grid, AC or DC grid. Also, the lines themselves could be divided into three possible types: 1) overhead, 2) underground, and 3) joint-nodes. Directional overcurrent relays (DOCRs) are preferred to protect distribution networks, because they can compromise between different design criteria. This invention utilizes the advanced features available in numerical DOCRs to locate faults in distribution networks. The measured operating time and the detected fault type are utilized to estimate the actual location of that fault using interpolation, regression, or even artificial neural networks (ANNs).

### TECHNICAL FIELD

Embodiments are generally related to electric power systems protection, and more specifically, in relays coordination and fault location subjects.

### BACKGROUND OF THE INVENTION

Any electric power system is exposed to different types of open- and short-circuit faults. To have a stable operation, five major stages should be accurately and precisely processed. These stages are listed as follows:
fault detection,
fault classification,
fault location,
fault containment, and
fault recovery.

This invention covers the first three stages given in Paragraph [002]. These three stages are graphically illustrated in FIG. 1.

The last two stages of Paragraph [002] are parts of what is called “fault isolation”, which are covered in power system stability topic.

The term “fault location” can be defined as: a process that locates the occurred fault with the lowest possible error.

During the past twenty years, many methods have been presented in the literature as effective fault locators. They could be based on:
Impedance (time- or phasor-domain),
travelling wave, or even using
power quality data,
superimposed components, or
artificial intelligence (AI) based algorithms.

Based on their designs, they could be exclusively used for:
transmission/sub-transmission lines (overhead, underground, and joint-nodes),
distribution systems,
micro-grids, or
smart-grids.

The internal fault location algorithm itself might be implemented into:
digital fault recorders (DFRs),
stand-alone fault locators, or even using
the state of the art numerical relays

The main differences between protective relays and fault locators are listed in FIG. 2.

In the literature, there is a fact that the primary protective devices preferred in distribution networks are directional overcurrent relays (DOCRs). One of the reasons is that these devices can compromise between different design criteria, such as:
installation and maintenance cost,
reliability (which is defined as security versus dependability),
simplicity,
adequateness,
operating speed, and
easy to discriminate between primary and backup relays.

Recently, the percentage of numerical DOCRs to other old technologies (i.e., electromechanical, solid-state, and hardware based digital DOCRs) continuously increases. Numerical DOCRs have many highly advanced features, such as:
their functions (i.e., internal algorithms) can be easily modified or replaced,
their settings can be remotely updated and changed,
their input and output data can be remotely monitored, stored, archived, and retrieved through some standard protocols, such as: IEC 608750-5, Modbus, MMS/UCA2, Courier, and DNP,
from currents and voltages measured on each phase, the fault type (i.e., the symmetrical and asymmetrical faults: single-phase to ground, double-phase, double-phase to ground, three-phase, and three-phase to ground) can be detected through their internal algorithm.
from the tag number of both end primary relays, the faulty line can be easily detected. Even if one of them fails to operate, the tag number of its backup relay(s) can also be utilized to determine the faulty zone, especially if the status of that inoperative primary relay and the contact condition of its circuit breaker are transmitted.

Based on that, one of the logical questions that should be raised is: why do we not effectively utilize these DOCRs to find the location of faults occur in distribution networks?

Thus, the invention presented here is about a new technique to locate short-circuit faults in distribution networks by utilizing the information recorded in both end numerical DOCRs of the faulty line.

To ensure the activated relays belong to the same line (i.e., both end primary relays), all the primary/backup (P/B) relay pairs should be correctly coordinated. This can be fulfilled by involving/merging the topic of “optimal relays coordination (ORC)”.

Even if one of the primary relays fails to operate the technique can still work, because numerical DOCRs have the ability to show the zones where they are installed in.

The idea here is to find a direct relationship between the operating time of these relays and the corresponding fault locations. To clarify this point, consider the fault 31 shown in FIG. 3. Suppose all the relays (i.e., R1 to R6) are correctly coordinated and work with their circuit breakers (i.e., CB1 to CB6) without any problem. The fault 31 can be cleared by the primary DOCRs 33 and 35 (i.e., R1 and R2 in FIG. 3) through initializing trip signals to their circuit breakers 32 and 34 (i.e., CB1 and CB2 in FIG. 3), respectively. If 32 or 33 fails to operate, then the backup DOCR 37 will initiate a trip signal to its circuit breaker 36, so the fault 31 can be completely cleared from the network. All P/B relay pairs are listed in the table of FIG. 4. The operating time of these inverse-time DOCRs can be governed by the following IEC/BS and ANSI/IEEE standard mathematical model:

$${T}_{{R}_{i}} = {TMS}_{i} \times [ \frac{{β}_{i}}{{( \frac{{I}_{{F}_{x} , {R}_{i}}}{{PS}_{i}} )}^{{α}_{i}} - 1} + {γ}_{i} ] \qquad Eq . ( 1 )$$

where
T_{R}_{ᵢ} is the operating time of the ith relay Rᵢ.
I_{F}_{ₓ}_{,R}_{ᵢ} is the short-circuit current occurred at the location x and seen by the ith relay; after being stepped-down through a current transformer (CT).
TMSᵢ and PSᵢ are respectively called the time-multiplier setting and the plug setting of the ith relay, which are considered as dependent variables in ORC problems.
αᵢ, βᵢ, and γᵢ are called the coefficients of the time-current characteristic curve (TCCC).

Using Eq.(1) gives an inverse relationship between the operating time and fault current. That is, as the current increases the operating time inversely decreases. There are different standard values for {αᵢ, βᵢ, γᵢ}. If the IEC inverse definite minimum time (IDMT) standard is used for Rᵢ, then αᵢ=0.02, βᵢ=0.14, and γᵢ=0; where FIG. 5 is an example of this TCCC.

It has been seen in Eq.(1) that the operating time T_{R}_{ᵢ} is a function of the fault magnitude I_{F}_{ₓ}_{,R}_{ᵢ} seen by Rᵢ. Also, it is known that the fault magnitude I_{F}_{ₓ}_{,R}_{ᵢ} is a function of the fault location x. That means:

I_{F}_{ₓ}_{,R}_{ᵢ}=I_{R}_{ᵢ}(x) Eq.(2)

Therefore, mathematically, it can be said that:

T_{R}_{ᵢ}(I_{R}_{ᵢ}(x))⇒T_{R}_{ᵢ}(x) Eq.(3)

Then, with an inverse function, the location x can be estimated as:

T_{R}_{ᵢ}(x)⇒x(T_{R}_{ᵢ}) Eq.(4)

However, the process is not simple, because:
The relationship between the operating time and fault location is non-linear.
There are some errors due to calculating, transmitting, displaying, and processing stages.
Uncertainties due to the weather and the surrounding conditions.
etc.

The mechanism of this invention is to precisely estimate the fault location x by:
Involving/merging the ORC topic to estimate the fault location x based on the recorded operating times of both end DOCRs. All the optimization stages are pre-defined in the OCR stage, so this technique is a semi-optimization-free technique.
Extracting the useful data from each numerical DOCR, which are listed in Paragraph [011].
Finding an appropriate function to approximate the inverse relationship given in Eq.(4), so it ends up with:

x=f(T_{R}_{ᵢ}^{near-end}, T_{R}_{ᵢ}^{far-end}) Eq.(5)

### BRIEF DESCRIPTION OF THE DRAWINGS

FIG. 1 gives a simplified framework of fault detection, classification, and location.

FIG. 2 shows the main differences between fault locators and protective relays.

FIG. 3 shows a simple 3-bus system.

FIG. 4 gives a table that lists the primary/backup (P/B) relay pairs of the system shown in FIG. 3.

FIG. 5 illustrates the behavior of a DOCR when it is equipped with IEC's IDMT-Based TCCC.

FIG. 6 shows the IEEE 8-bus test system, which is also simulated during validating this invention numerically.

FIG. 7 depicts the cases of fault probability zones (FPZs) where the fault location estimated from a one end relay does not match with the location estimated from the other end relay.

FIG. 8 shows the algorithm used with this invention if the fault location is estimated based on linear and non-linear interpolation approaches.

FIG. 9 shows the algorithm used with this invention if the fault location is estimated based on linear and non-linear regression approaches.

FIG. 10 gives the “double-line to ground” and “three-phase” short-circuit currents measured on the line 66 of FIG. 6 with different locations of 63. These measurements are taken from the both end relays 61 and 62 of FIG. 6.

FIG. 11 gives the optimal values of TMS and PS of 61 and 62 shown in FIG. 6, which are obtained by solving the ORC problem of FIG. 6 for the near-end three-phase faults for both relays 61 and 62.

FIG. 12 shows the R-code used to regress the relationship between the operating time of R14 (i.e. 61 in FIG. 6) and the fault location 63 shown in FIG. 6 using a non-linear asymptotic equation given in Eq.(12) and numerically obtained in Eq.(17).

FIG. 13 shows the accuracy of different fault locators against the actual fault location. The readings are taken from R7 (i.e., 62 in FIG. 6).

FIG. 14 shows the accuracy of different fault locators against the actual fault location. The readings are taken from R14 (i.e., 61 in FIG. 6).

FIG. 15 shows the overall difference between the actual and the estimated fault locations that are obtained by taking the average of the readings given in FIG. 13 and FIG. 14.

FIG. 16 shows the numerical readings of the graphical plots given in FIG. 13, FIG. 14, and FIG. 15.

FIG. 17 shows an illustrated neural network topology to estimate fault locations based on one end DOCR's operating times. This topology can be applied to estimate the fault location 63 of FIG. 6 based on the pre-determined short circuit analysis given in FIG. 10 for the relay R7 (i.e., 62 in FIG. 6). Thus, this approach can be used to have the same concept of interpolation- and regression-based approaches.

FIG. 18 shows an illustrated neural network topology to estimate fault locations based on one end DOCR's operating times. This topology can be applied to estimate the fault location 63 of FIG. 6 based on the pre-determined short circuit analysis given in FIG. 10 for the relay R14 (i.e., 61 in FIG. 6). Thus, this approach can be used to have the same concept of interpolation- and regression-based approaches.

FIG. 19 shows an illustrated neural network topology to estimate fault locations based on both end DOCRs' operating times. This topology can be applied to estimate the fault location 63 of FIG. 6 based on the pre-determined short circuit analysis given in FIG. 10 for the relays R7 and R14 (i.e., 62 and 61 in FIG. 6, respectively). Thus, this approach can be used directly to estimate fault locations without taking the average value of both end relays as done with interpolation- and regression-based approaches as well as ANN topologies presented in FIG. 17 and FIG. 18.

FIG. 20 estimates the fault location 63 of FIG. 6 when the ANN topology given in FIG. 19 is executed in python with the following configuration: 2 inputs R7 and R14 (i.e., 62 and 61 in FIG. 6, respectively), one output (i.e., the fault location x) with a linear transfer function, one hidden layer with 10 neurons and a logarithmic sigmoid transfer function, and the training stage is carried out using the gradient descent back-propagation algorithm.

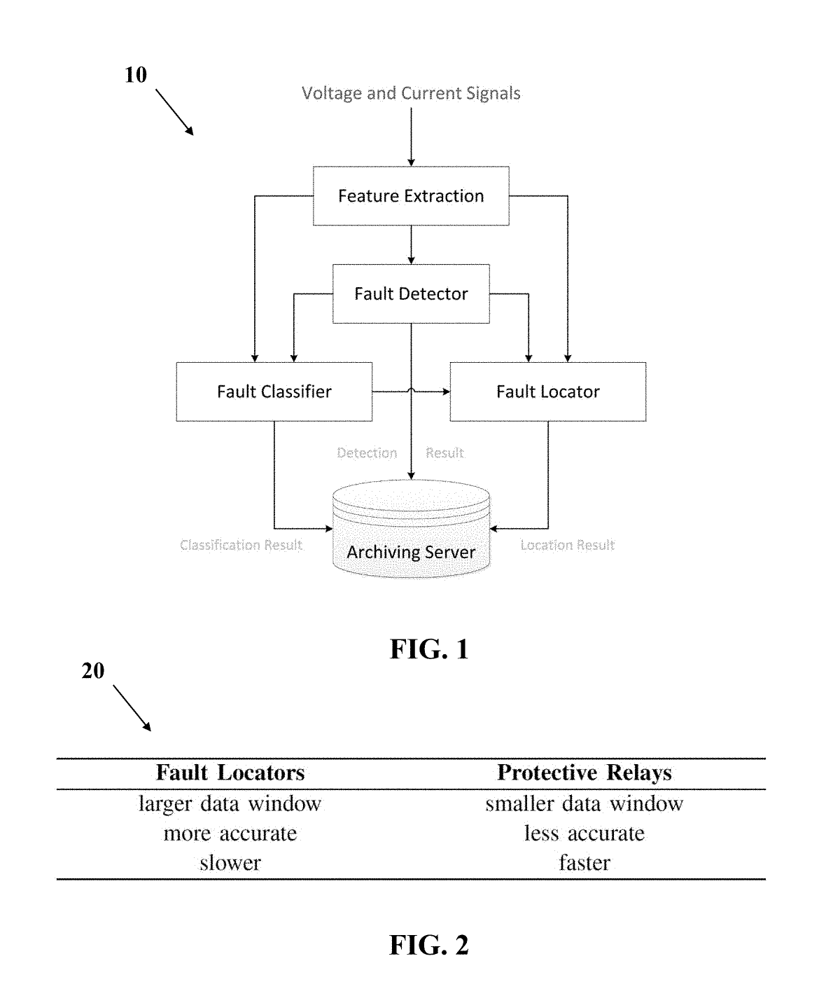

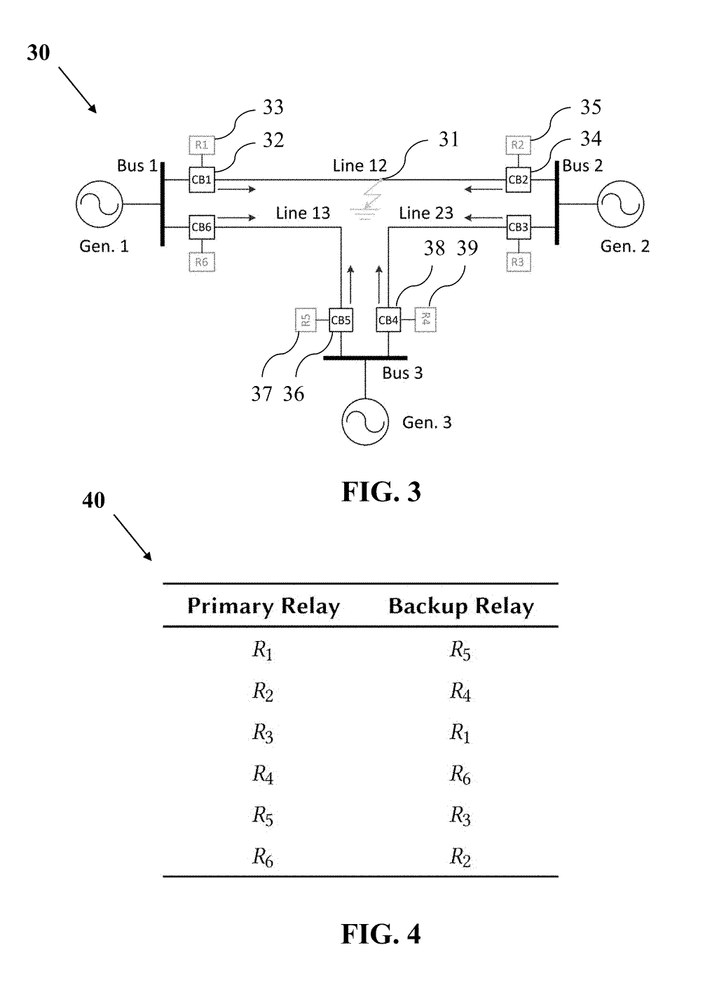

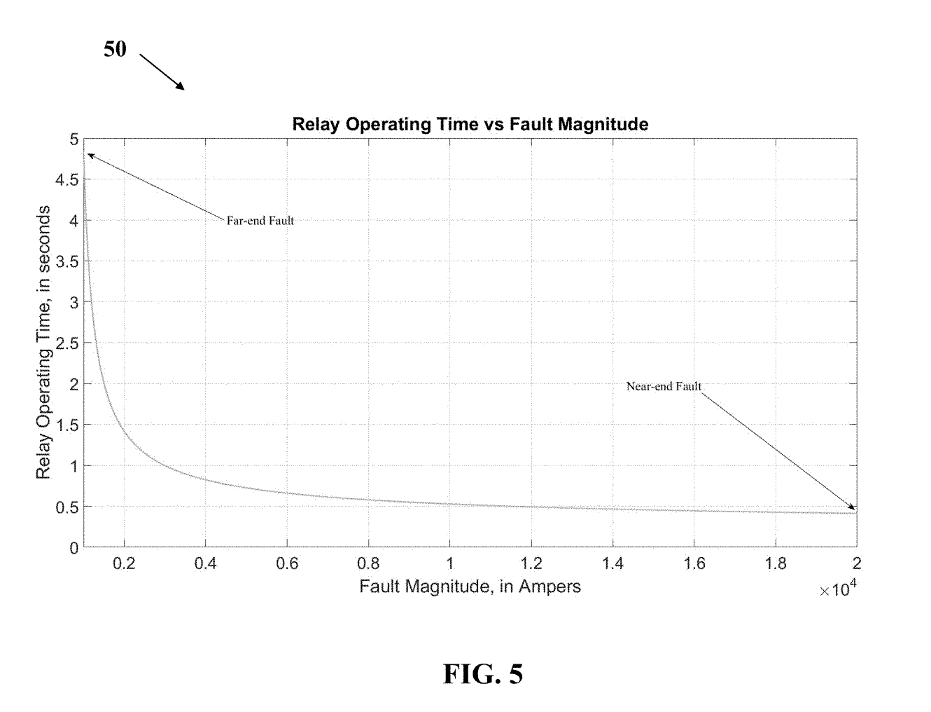

### DETAILED DESCRIPTION

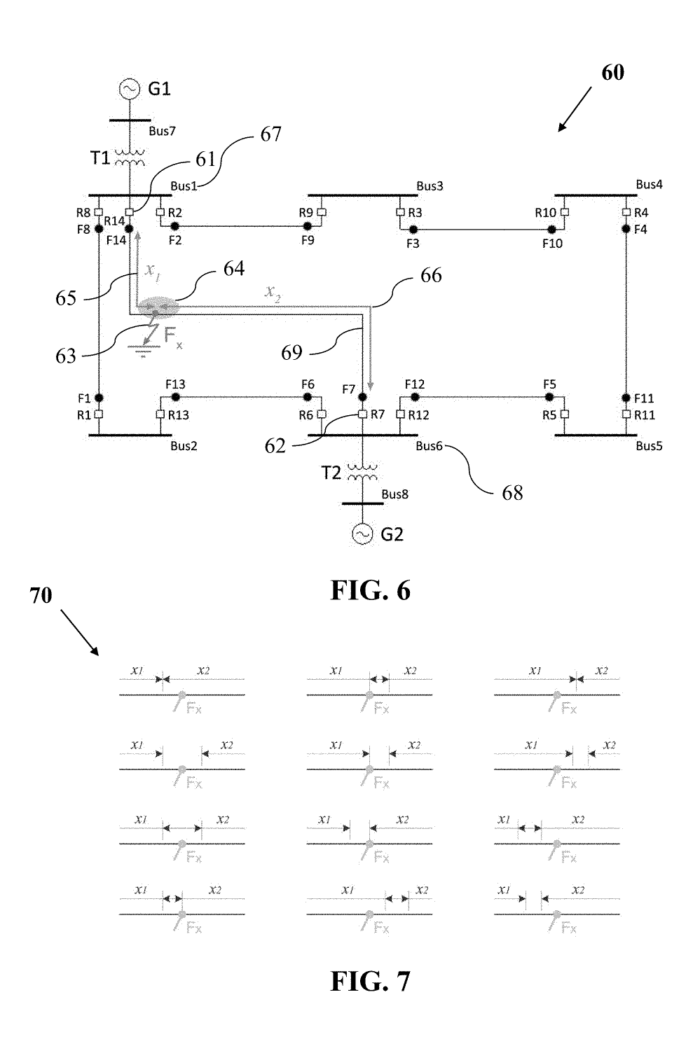

It has been seen that the location of any fault can be estimated by measuring the operating times recorded in both end DOCRs of that faulty line. However, the fault location calculated from one end DOCR does not necessarily meet with the same fault location calculated from the other DOCR. That is, from FIG. 6, the distance 65 (i.e., x₁) could not be equal to the actual distance calculated from 67 to 63. Similarly, the distance 66 (i.e., x₂) could not be equal to the actual distance calculated from 68 to 63.

From the preceding uncertainties, the total length of the faulty line L₁₆ between 67 (i.e., Bus-1) and 68 (i.e., Bus-6) of FIG. 6 can be estimated as follows:

length(L₁₆)=l_{L}_{₁₆}≈x₁+x₂ Eq.(6)

where l_{L}_{₁₆} is the branch or line between Bus-1 (i.e., 67) and Bus-6 (i.e., 68) of FIG. 6. x₁ and x₂ are the distances 65 and 66 of FIG. 6 that need to be estimated based on the operating times measured form the relays 61 and 62, respectively.

Based on that, there are many possibilities that the location estimated by near-end and far-end relays does not match with the actual fault location. Such these fault probability zones (FPZs) highlighted by 64 in FIG. 6 are graphically shown in FIG. 7.

Thus, the average of the estimated values calculated by 61 and 62 of FIG. 6 is used to reduce the overall error as follows:

$$\begin{matrix}{x}_{Bus - 1} = \frac{{x}_{1} + ( {l}_{{L}_{16}} - {x}_{2} )}{2} & Eq . ( 7 ) \\ {x}_{Bus - 6} = \frac{{x}_{2} + ( {l}_{{L}_{16}} - {x}_{1} )}{2} & Eq . ( 8 )\end{matrix}$$

where x_{Bus-1} is the estimated distance to 63; if started from 67. Similarly, x_{Bus-6} is the estimated distance to 63; if started from 68.

During describing this invention, the node 67 (i.e., Bus-1 of FIG. 6) is selected as a reference, so Eq.(7) is used instead of Eq.(8). Also, for the sake of simplicity, the notation x_{Bus-1} is replaced with just x.

As said before, the goal is to find a relationship between the fault location of a faulty line and the operating times of both end DOCRs. For the test system given in FIG. 6, the fault location is 63 and both end relays are those installed at points 61 and 62.

To accomplish the preceding goal in Paragraph [048], four different interpolation- and regression-based approaches are initially proposed as follows:
Classical Linear Interpolation:

$${x}_{i} = {x}_{i}^{min} - ( {x}_{i}^{min} - {x}_{i}^{max} ) \cdot [ \frac{{T}_{{R}_{i}}^{min} - {T}_{{R}_{i}}^{{F}_{x}}}{{T}_{{R}_{i}}^{min} - {T}_{{R}_{i}}^{{ }_{max}}} ] \qquad Eq . ( 9 )$$

Logarithmic-Based Non-Linear Interpolation:

$${x}_{i} = {x}_{i}^{min} - ( {x}_{i}^{min} - {x}_{i}^{max} ) \cdot [ \frac{log ( {T}_{{R}_{i}}^{min} ) - log ( {T}_{{R}_{i}}^{{F}_{x}} )}{log ( {T}_{{R}_{i}}^{min} ) - log ( {T}_{{R}_{i}}^{{ }_{max}} )} ] \qquad Eq . ( 10 )$$

Cubic Regression Model:

xᵢ=θ₀+θ₁T_{R}_{ᵢ}+θ₂T_{R}_{ᵢ}²+θ₃T_{R}_{ᵢ}³ Eq.(11)
Asymptotic Regression Model:

xᵢ=θ₀+θ₁ exp(θ₂T_{R}_{ᵢ}) Eq.(12)
where T_{R}_{ᵢ}^{min} and T_{R}_{ᵢ}^{max} are respectively the minimum and maximum operating times of the ith relay, and T_{R}_{ᵢ}^{F}^{ₓ} is the operating time of that relay during the occurrence of the fault Fₓ. xᵢ^{min} and xᵢ^{max} are respectively the minimum and maximum distances seen by the ith relay. θ₀ to θ₃ are the regression coefficients.

After that, we have proposed a novel non-linear regression model that inverses Eq.(1) to extract l_{F}_{ₓ}_{,R}_{ᵢ} and represent it as a function of T_{R}_{ᵢ}. That is, changing the mode from a time-current characteristic curve (TCCC) to a current-time characteristic curve (CTCC):

$$f ( x ) = {I}_{{F}_{x} , {R}_{i}} = {I}_{{R}_{i}} ( {T}_{{R}_{i}} ) = {PS}_{i} \times {[ \frac{{β}_{i} {TMS}_{i}}{{T}_{{R}_{i}} - {γ}_{i} {TMS}_{i}} + 1 ]}^{1 / {α}_{i}} \qquad Eq . ( 13 )$$

To find a direct relationship between the fault distance x and the operating time of the ith relay, the concept given in Eqs.(2)-(4) is applied here. Thus, the preceding CTCC given in Eq.(13) is further modified to be as a distance-time characteristic curve (DTCC) as follows:

$${x}_{i} = {θ}_{0} \times {[ \frac{{θ}_{1}}{{T}_{{R}_{i}} + {θ}_{2}} + {θ}_{3} ]}^{{θ}_{4}} \qquad Eq . ( 14 )$$

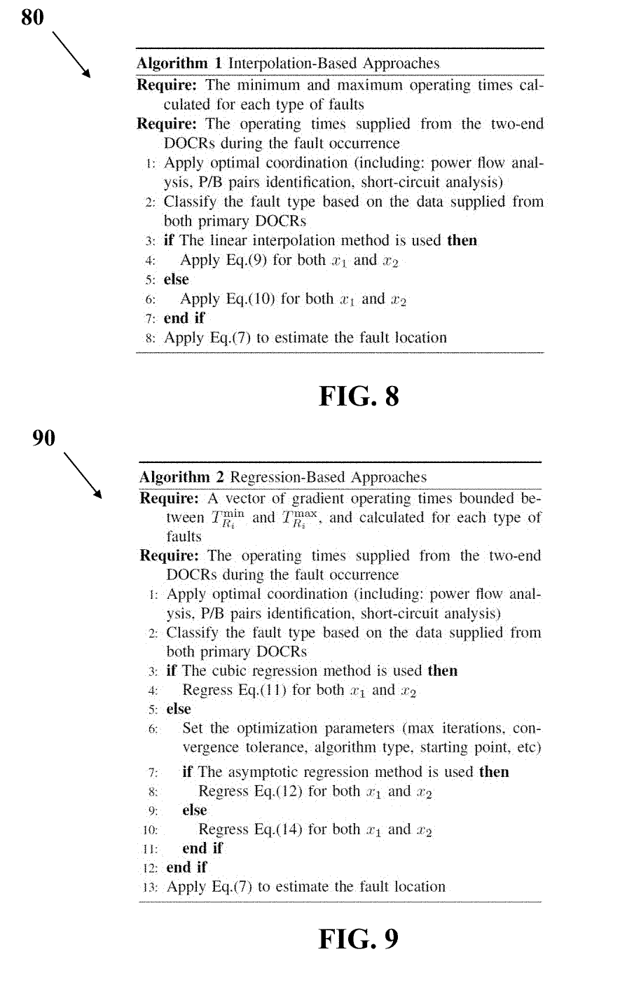

The mechanism of the interpolation-based approaches is explained by the first algorithm given in FIG. 8, while the mechanism of the regression-based approaches is explained by the second algorithm given in FIG. 9.

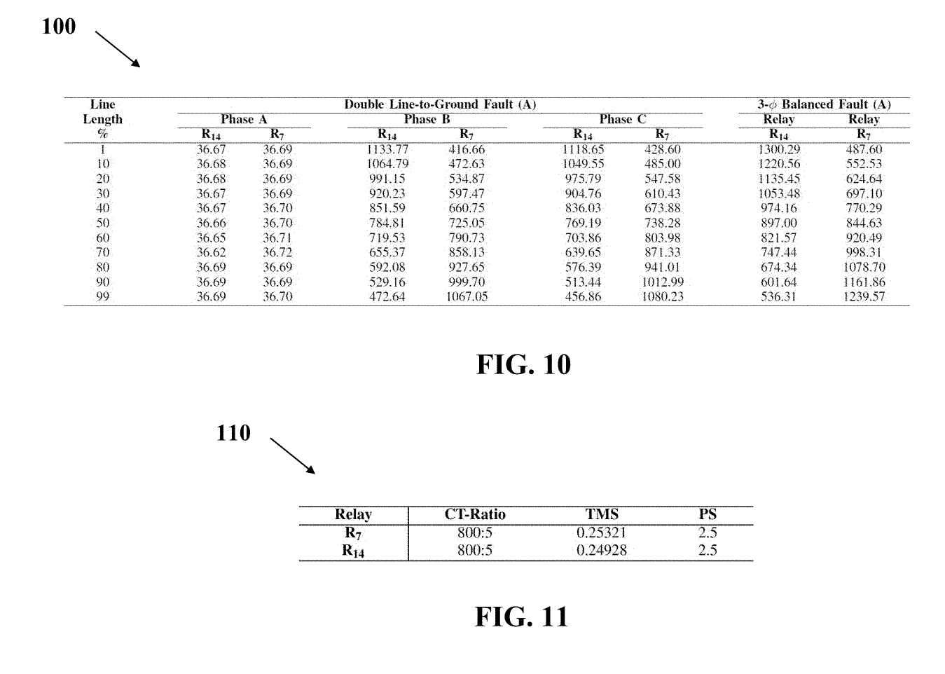

To analyze the performance of these estimators, the test system shown in FIG. 6 is simulated using asymmetrical “double-line to ground” and symmetrical “three-phase” fault types at different locations of the line 69. These fault analyses are tabulated in the table given in FIG. 10. The CT-Ratio and the optimal values obtained by the ORC stage for the independent variables TMS and PS of both end relays 61 and 62 of FIG. 6 all are tabulated in the table given in FIG. 11.

The solutions obtained for the coefficients of Eq.(11), Eq.(12), and Eq.(14) are obtained as follows:
Cubic Regression Models for the distances 65 and 66 of FIG. 6 are:

x₁=−185.1+182.6T_{R}_{₁₄}−40.9T_{R}_{₁₄}²+3.068T_{R}_{₁₄}³ Eq.(15)

x₂=231.2−117.3T_{R}_{₇}+20.29T_{R}_{₇}²−1.125T_{R}_{₇}³ Eq.(16)
Asymptotic Regression Models for the distances 65 and 66 of FIG. 6 are:

x₁=97.5874−394.992 exp(−0.977242T_{R}_{₁₄}) Eq.(17)

x₂=4.58289+334.479 exp(−0.834915T_{R}_{₇}) Eq.(18)
DTCC-Based Regression Models for the distances 65 and 66 of FIG. 6 are:

$$\begin{matrix}{x}_{1} = 107.281 \times {[ \frac{- 0.909642}{{T}_{{R}_{14}} - 0.625779} + 1.10327 ]}^{1.11022} & Eq . ( 19 ) \\ {x}_{2} = 8.38581 \times {[ \frac{12.5161}{{T}_{{R}_{7}} - 0.336438} - 1.2904 ]}^{1.12257} & Eq . ( 20 )\end{matrix}$$

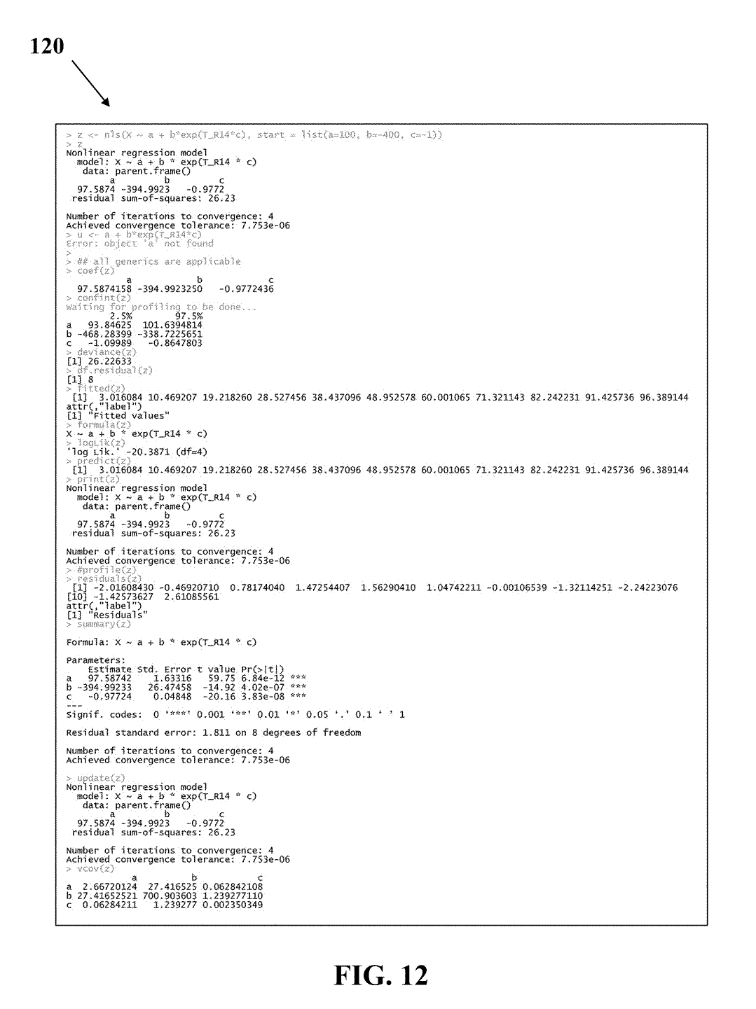

The coefficients of Eq.(11) can be obtained by applying the linear least square fitting technique or any other technique. While the coefficients of Eq.(12) and Eq.(14) can be obtained by using non-linear regression approaches. For example, FIG. 12 shows the R-code used to obtain the coefficients of Eq.(17). It is important to say that the coefficients given in Eqs.(17)-(20) depend on the starting points during initializing these non-linear regression models.

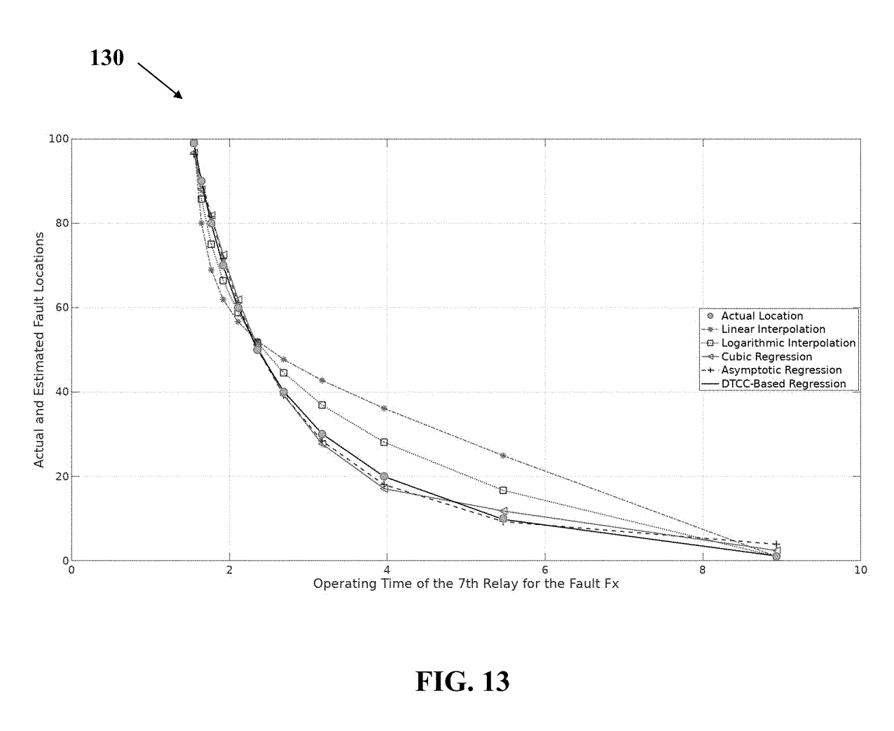

Applying these models with the operating times calculated using Eq.(1) and the balanced three-phase fault currents given in FIG. 10 plus the optimal settings of the 7^{th} relay (i.e., 62 in FIG. 6) gives the plots in FIG. 13. From these plots, it is clear that the best model that matches the exact fault location is Eq.(20).

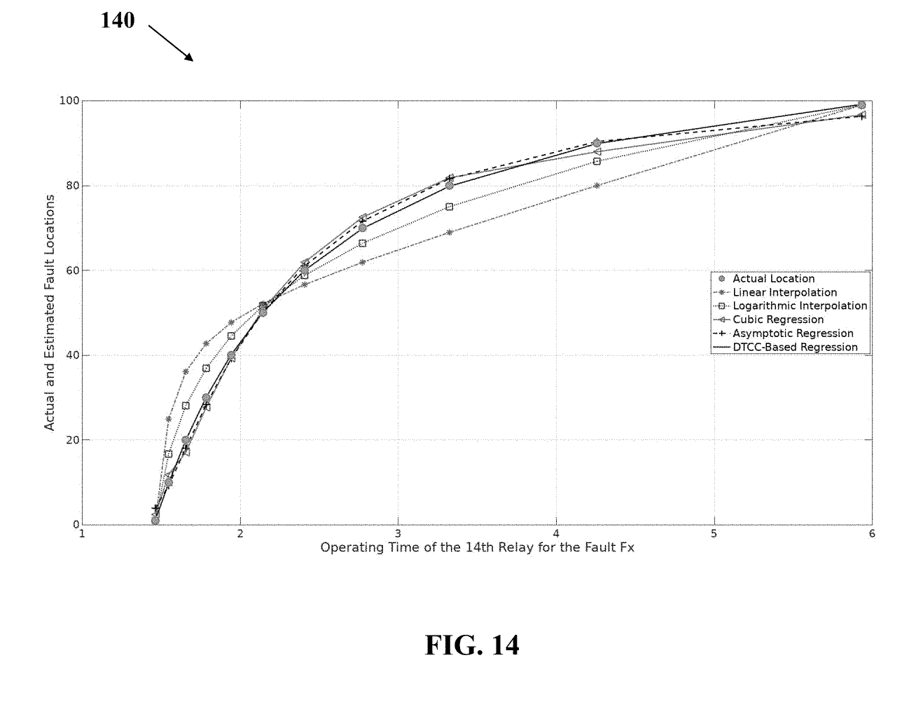

Similar thing can be done for the 14^{th} relay (i.e., 61 in FIG. 6), where the corresponding plots are given in FIG. 14. Again, the best fault locator is the one modeled based on DTCC, which is given in Eq.(19).

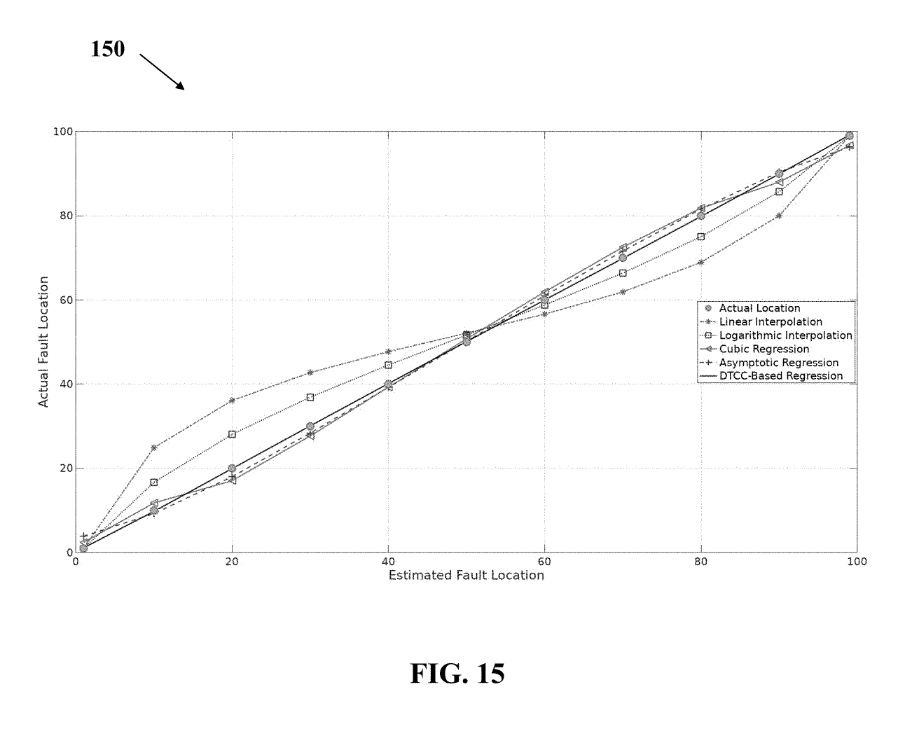

By taking the average of each fault location estimated by both end relays 61 and 62 of FIG. 6, then the difference between the actual and estimated fault locations obtained by the preceding interpolation- and regression-based models are shown in FIG. 15. It is obvious that the best average estimator is the one that is based on the DTCC-based regression models presented in Eq.(19) and Eq.(20).

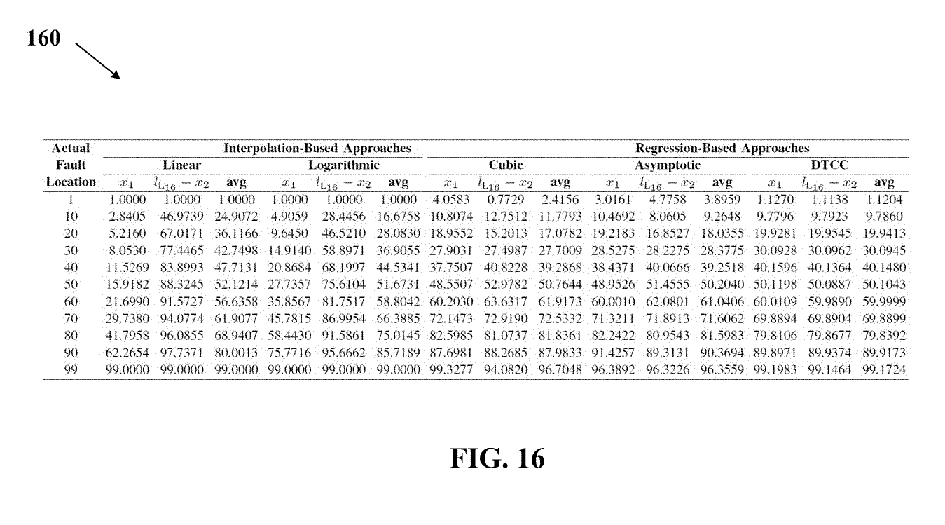

The numerical values of x₁, x₂, and avg=[x₁+(l_{L}_{₁₆}−x₂)]/2 for all the three regression-based models are listed in FIG. 16.

Because of many uncertainty sources, it has to be said that the realistic fault location does not necessarily follow the DTCC shapes of both end relays. If we suppose there are U disturbances affecting the overall performance of the DTCC-based regression model, then they can be translated as the sum of errors Σⱼ₌₁^{U}εⱼ applied to Eq.(14). Thus, the modified DTCC-based regression model becomes:

$${x}_{i} = {θ}_{0} \times {[ \frac{{θ}_{1}}{{T}_{{R}_{i}} + {θ}_{2}} + {θ}_{3} ]}^{{θ}_{4}} + {\sum }_{j = 1}^{U} {ɛ}_{j} \qquad Eq . ( 21 )$$

If these residuals are unbiased and they satisfy the normality assumptions, then the actual fault locations are supposed to be normally distributed below and above the DTCC curve shown in FIG. 15.

Although the performance of the interpolation-based methods is not good, it can be enhanced if the nearest neighbor pre-defined operating times are used instead of sticking on just T_{R}_{ᵢ}^{min} and T_{R}_{ᵢ}^{max}. That is, processing the interpolation technique inside a moving window of pre-defined operating times.

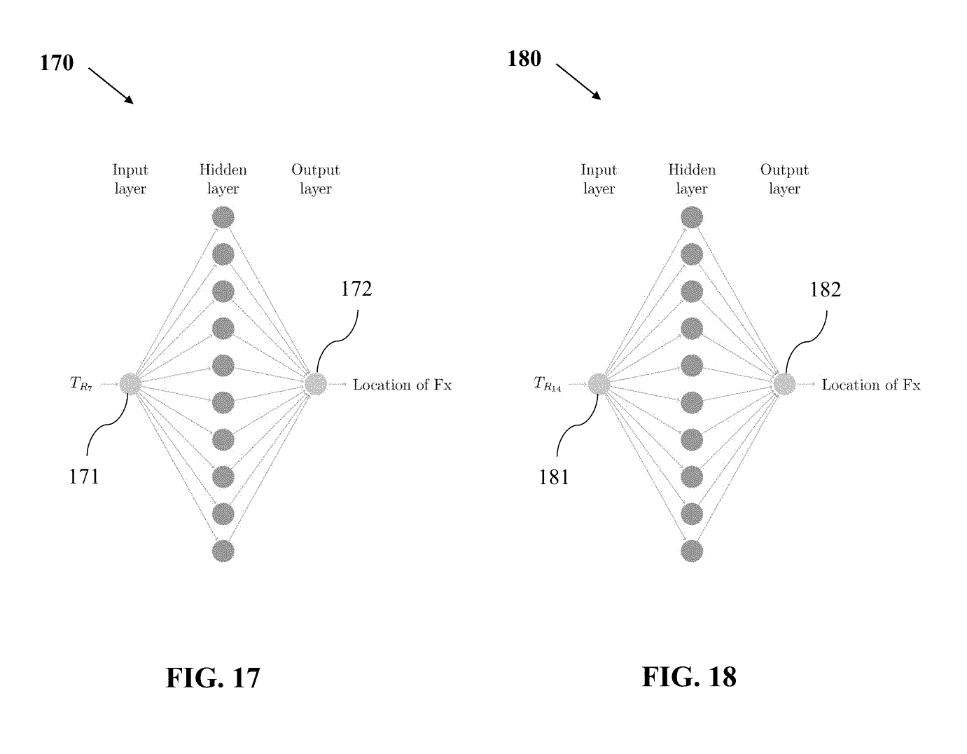

The other possible approach is to use ANNs as function approximators for both end relays. Thus, if the operating times of the relays R7 and R14 (i.e., 62 and 61 in FIG. 6) are used to estimate the fault location 63, then FIG. 17 represents the neural network of 62 and FIG. 18 represents the neural network of 61. Based on that, the fault location 63 can be estimated by averaging the outputs of FIG. 17 and FIG. 18 using Eq.(7) or Eq.(8).

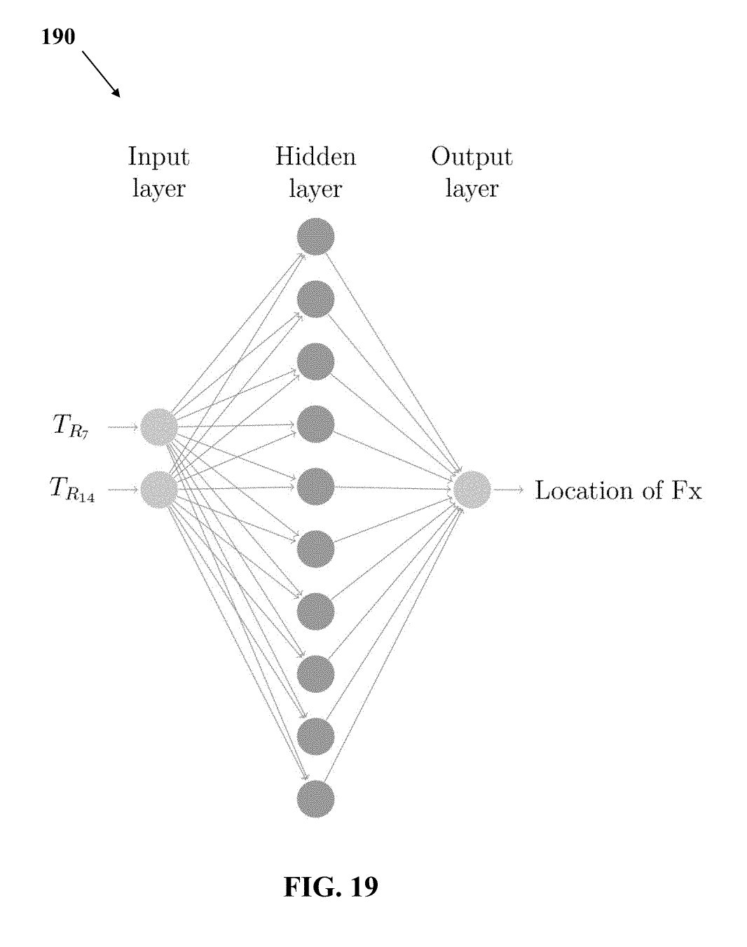

Instead of that, the two operating times of 61 and 62 in FIG. 6 can be directly utilized in a one neural network to estimate the fault location 63 without taking their average value. This new topology is shown in FIG. 19.

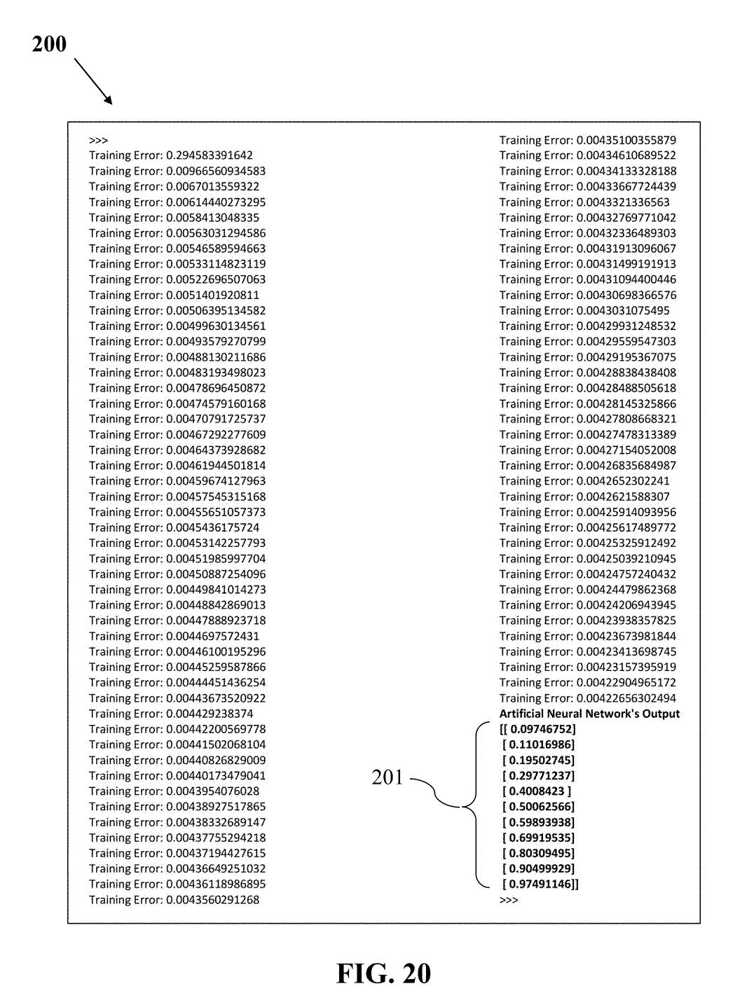

If the neural network given in FIG. 19 is applied to solve the preceding numerical problem of FIG. 6, then the numerical solution presented in 201 of FIG. 20 for the fault locations mentioned in FIG. 10 is obtained. Here, in this example, the neural network is coded in Python language using the configuration given in Paragraph [042].

It has to be said that the idea given in FIG. 17, FIG. 18, and FIG. 19 can be expanded to use any other artificial intelligence (AI) based function approximation technique, such as employing support vector machine (SVM).

A hybridization is possible between all the techniques given in this invention (i.e., hybridizing between interpolation/regression/AI), where fuzzy systems can also be employed to account uncertainties due to both randomness and fuzziness.

Also, any other regression based model can be used including step-wise regression approaches. Also, the coefficients of Eq.(14) can be reduced. For example, the following equation could be used:

$${x}_{i} = \frac{{θ}_{0}}{{T}_{{R}_{i}} + {θ}_{1}} + {θ}_{2} \qquad Eq . ( 22 )$$

The numerical values of the three coefficients of Eq.(22) obtained for R14 and R7 (i.e., 61 and 62 in FIG. 6) are:

$$\begin{matrix}{x}_{1} = \frac{- 118.0411}{{T}_{14} - 0.4844} + 121.1775 & Eq . ( 23 ) \\ {x}_{2} = \frac{116.037}{{T}_{{R}_{7}} - 0.521} - 13.336 & Eq . ( 24 )\end{matrix}$$

1. A numerical directional overcurrent relays based short-circuit fault locator, comprising:
a good communication between said numerical directional overcurrent relays (DOCRs) and the corresponding substation or central control room;
wherein the primary/backup (P/B) pairs of said DOCRs are correctly coordinated and all the useful information recorded in said DOCRs are transmitted to said substation or said central control room;
wherein the coordination stage can be accomplished by setting the time multiplier setting (TMS) and the plug setting (PS) of all said DOCRs through solving the optimal relay coordination (ORC) problem of a given electric network;
wherein said the useful information provided by said DOCRs are: tag numbers and zones, operating times, fault currents and voltages measured on each phase, fault type, operating/health status, contact status of circuit breakers (CBs).
The mechanism of this invention is based on estimating fault locations based on said fault types detected by said DOCRs and operating times recorded from said DOCRs installed on both ends of a faulty line.
The mechanism of this invention still works even if one of said DOCRs or its said CB fails to operate where the other said DOCRs have the ability to show the suspected said faulty line by discriminating between the zones of said primary/backup pairs of said DOCRs.

2. The relationship between said fault locations and said operating times of said DOCRs can be expressed through linear/non-linear interpolation processes, linear/nonlinear regression models, or by applying artificial intelligence (AI) such as artificial neural networks (ANNs), support vector machine (SVM), or any function approximator that is based on said AI;
wherein the performance of said linear/nonlinear interpolation processes can be enhanced by interpolating between two updatable points based on said operating times recorded instead of depending on the lower and upper limits of said operating times;
wherein said linear/nonlinear regression models can be expressed as continuous or step-wise functions.
wherein said distance-time characteristic curve (DTCC) is a novel nonlinear equation that provides highly accurate fitting where its five coefficients can be reduced down to four or even three coefficients.
wherein said ANNs can be constructed for each one of said DOCRs and then taking the average value.
wherein said ANNs can also be constructed for said both end DOCRs directly in a one topology so it is not required to calculate said average value.
wherein the fuzzy systems can be embedded in any of said linear/nonlinear interpolation processes, said linear/nonlinear regression models, or said AI-based function approximators so the uncertainty due to fuzziness and randomness can both be accounted.

3. The whole process of claim 1 and claim 2 could also cover the other types of relays and if each end of said faulty line has double primary protective devices or not;
wherein said DOCRs could be equipped with a definite current or a definite time equation instead of an inverse time equation;
wherein the directional unit of said DOCRs could be not available so the protective devices in this case are the classical nondirectional overcurrent relays (OCRs);
wherein protection designs with said double primary protective devices could be between two of said DOCRs or between said one DOCR and a distance or any other relay.
